(19) United States
(12) Patent Application Publication
(10) Pub. No.: US 2026/0033000 A1
(43) Pub. Date: Jan. 29, 2026

(54) SEMICONDUCTOR DEVICE

(71) Applicant: Socionext Inc., Kanagawa (JP)

(72) Inventors: Hirotaka TAKENO, Yokohama (JP); Wenzhen WANG, Yokohama (JP); Atsushi OKAMOTO, Yokohama (JP)

(21) Appl. No.: 19/351,386

(22) Filed: Oct. 7, 2025

Related U.S. Application Data
(63) Continuation of application No. PCT/JP2023/014837, filed on Apr. 12, 2023.

(51) Int. Cl. H10D 84/90; H10D 89/10

(52) U.S. Cl. CPC H10D 84/981; H10D 84/961; H10D 89/10

(57) ABSTRACT

A semiconductor device includes a substrate in which a via is formed, first through third power supply lines each formed below the substrate and extending in a first direction, and a power switch circuit including a first transistor and a second transistor each formed above the substrate. The first transistor is coupled between the first power supply line and the second power supply line, and the source of the first transistor is coupled to the via coupled to the first power supply line. The second transistor is arranged at a position overlapping the position of the second power supply line, and the source of the second transistor is coupled to the source of the first transistor via an interconnect formed above the substrate.

### CROSS-REFERENCE TO RELATED APPLICATIONS

This application is a continuation application of International Application No. PCT/JP2023/014837 filed on April 12, 2023, and designated the U.S., the entire contents of which are incorporated herein by reference.

### BACKGROUND

### 1. Technical Field

The present invention relates to a semiconductor device.

### 2. Description of Related Art

It is known to provide a power switch circuit for switching a power source between supplying and shutting off power to a transistor in a semiconductor device such as a standard cell. A backside power delivery network (BSPDN) technology in which a power supply line is provided on a back surface of a semiconductor substrate and power is supplied to a transistor provided on a front surface of the semiconductor substrate via a through silicon via (TSV). A technology of directly coupling vias to a source and a drain of a transistor provided on the front surface of a semiconductor substrate from the back surface of the semiconductor substrate is known.

Patent Document 1: U.S. Patent Application Publication No. 2022/0344263

Patent Document 2: U.S. Patent Application Publication No. 2022/0208757

Patent Document 3: U.S. Patent Application Publication No. 2021/0272903

Patent Document 4: U.S. Patent Application Publication No. 2019/0305773

Patent Document 5: International Publication No. WO 2020/065916

Patent Document 6: International Publication No. WO 2022/066797

Patent Document 7: U.S. Pat. No. 11,552,069

### SUMMARY

According to one aspect of the present disclosure, a semiconductor device includes a substrate in which a first via is formed, a first power supply line supplied with a first potential, a second power supply line supplied with a second potential, and a third power supply line supplied with a third potential, the first power supply line, the second power supply line, and the third power supply line being formed below the substrate, and a power switch circuit including a first transistor formed above the substrate and electrically coupled between the first power supply line and the second power supply line and a second transistor formed above the substrate. The first power supply line, the second power supply line, and the third power supply line each extend in a first direction in a plan view. The first transistor includes a first source and a first drain. The first transistor is arranged at a position overlapping the first power supply line in a plan view. The first source is coupled to the first via coupled to the first power supply line. The second transistor includes a second source and a second drain. The second transistor is arranged at a position overlapping the second power supply line in a plan view. The second source is electrically coupled to the first source via an interconnect formed above the substrate.

### BRIEF DESCRIPTION OF THE DRAWINGS

FIG. 1 is a plan view illustrating an example of a layout in a semiconductor device according to a first embodiment;

FIG. 2 is a cross-sectional view illustrating an example of a cross-sectional structure of the semiconductor device of FIG. 1;

FIG. 3 is a circuit diagram illustrating an example of a circuit arranged in a standard cell block of FIG. 1;

FIG. 4 is a plan view illustrating a positional relationship between power supply lines, virtual power supply lines, ground lines, and vias, all of which are arranged in the back surface side of a semiconductor substrate at respective positions overlapping the standard cell block of FIG. 3, and power switch circuits PSW in a plan view;

FIG. 5 is a plan view illustrating an example of a layout in the power switch circuit illustrated in FIGS. 3 and 4;

FIG. 6 is a cross-sectional view illustrating an example of a cross section taken along line X1-X2 in FIG. 5;

FIG. 7 is a cross-sectional view illustrating another example of a cross section taken along line X1-X2 in FIG. 5;

FIG. 8 is a cross-sectional view illustrating yet another example of a cross section taken along line X1-X2 in FIG. 5;

FIG. 9 is a plan view illustrating a first modified example of a layout in the power switch circuit illustrated in FIG. 3;

FIG. 10 is a plan view illustrating a second modified example of a layout in the power switch circuit illustrated in FIG. 3;

FIG. 11 is a plan view illustrating a third modified example of a layout in the power switch circuit illustrated in FIG. 3;

FIG. 12 is a plan view illustrating a fourth modified example of a layout in the power switch circuit illustrated in FIG. 3;

FIG. 13 is a plan view illustrating a fifth modified example of a layout in the power switch circuit illustrated in FIG. 3;

FIG. 14 is a plan view illustrating an example of a layout in power supply lines arranged on a back surface side of a semiconductor substrate in a semiconductor device of a second embodiment;

FIG. 15 is a plan view illustrating an example of a layout in the power switch circuit illustrated in FIG. 14; and

FIG. 16 is a plan view illustrating a modified example of a layout in the power switch circuit illustrated in FIG. 14.

### DETAILED DESCRIPTION

Specific studies have not been conducted regarding how to arrange and couple interconnects and vias, etc. in the case where a power supply line formed below a semiconductor substrate and the source and drain of a power supply switch circuit formed above the semiconductor substrate are directly coupled by the vias formed in the semiconductor substrate. For example, how a source of a transistor above a semiconductor substrate, that is not arranged at a position overlapping the power supply line below the semiconductor substrate in a plan view, is electrically coupled to a power supply line below the semiconductor substrate has not been considered.

According to the present disclosure, there is provided a power switch circuit in which a source of a transistor that does not overlap a power supply line below a semiconductor substrate in a plan view can be electrically coupled to the power supply line below the semiconductor substrate.

Hereinafter, embodiments will be described with reference to the drawings. In the descriptions hereinafter, a symbol indicating a signal is also used as a symbol indicating a signal line or a signal terminal. A symbol indicating a power supply potential is also used as a symbol indicating a power supply line or a power supply terminal to which the power supply potential is supplied.

### (First Embodiment)

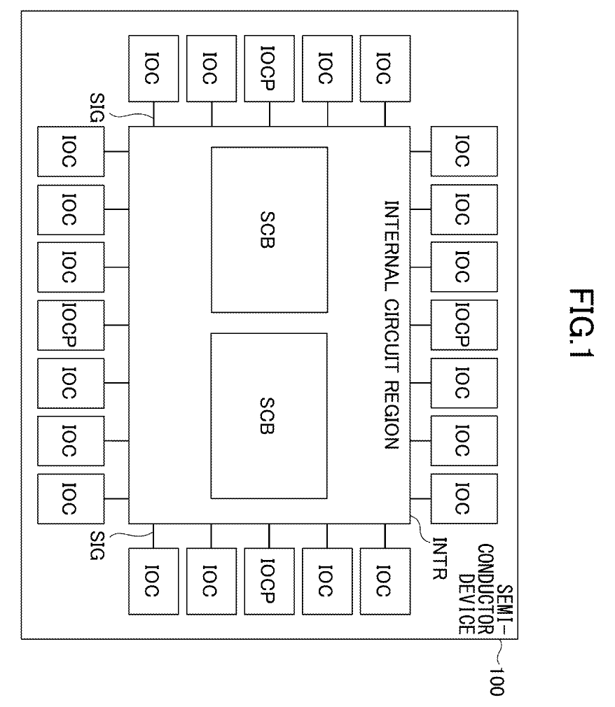

FIG. 1 illustrates an example of a layout in a semiconductor device according to the first embodiment. For example, the semiconductor device 100 illustrated in FIG. 1 may be a system-on-a-chip (SoC), a single field-programmable gate array (FPGA), or the like.

The semiconductor device 100 includes a plurality of I/O cells IOC and IOCP and an internal circuit region INTR. The I/O cell IOC is an interface circuit for a signal SIG such as an input signal, an output signal, or an input/output signal. The I/O cell IOCP is an interface circuit for a power supply potential or a ground potential.

The I/O cells IOC and IOCP are coupled to the internal circuit region INTR. For example, the internal circuit region INTR includes one or more standard cell blocks SCB in which standard cells are provided. In the internal circuit region INTR, a logic circuit other than the standard cell may be mounted, or a memory may be mounted. A memory may be mounted in the standard cell block SCB. For example, a transistor mounted on the semiconductor device 100 may be a fin field effect transistor (FET), a nanosheet FET, or a complementary FET (CFET).

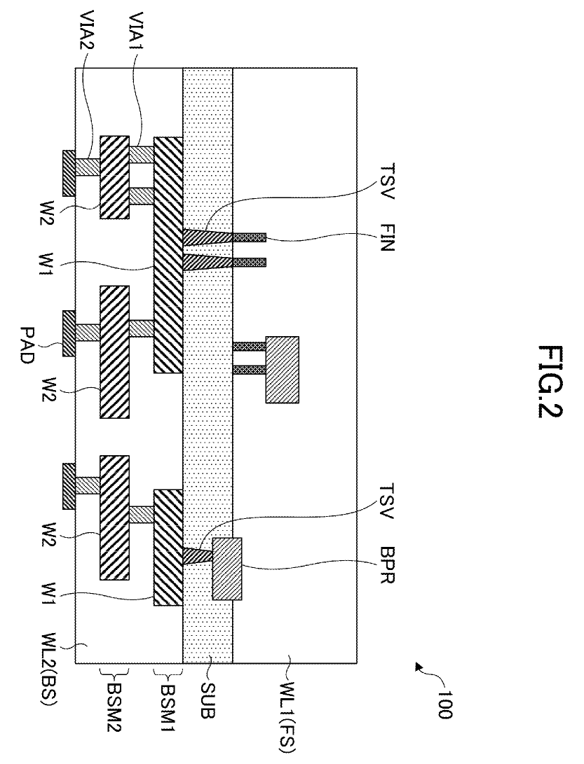

FIG. 2 illustrates an example of a cross-sectional structure of the semiconductor device 100 of FIG. 1. The semiconductor device 100 includes a substrate SUB, an interconnect layer WL1 formed on a front surface side FS of the substrate SUB, and an interconnect layer WL2 formed on a back surface side BS of the substrate SUB. The front surface side FS of the substrate SUB is an example of a side above the substrate SUB, and the back surface side BS of the substrate SUB is an example of a side below the substrate SUB. A fin FIN which is a part of a transistor is formed on the surface of the substrate SUB. The fin FIN has a source, a drain, and a channel. A pad PAD, which is an external coupling terminal, is formed on the surface (back surface) opposite to the surface on which the substrate SUB is provided in the interconnect layer WL2.

The interconnect layer WL2 includes a plurality of interconnect layers BSM1 and BSM2 (two layers in FIG. 2, and BSM is an abbreviation of “backside metal”). For example, the interconnect layers BSM1 and BSM2 are respectively formed with interconnects W1 and W2 that respectively supply a power source potential and a ground potential. The interconnects W1 and W2 are coupled to each other through a via VIA1. The interconnect W2 and the pad PAD are coupled to each other through a via VIA2.

The interconnect W1 is coupled to the source of the fin FIN via a through silicon via (TSV) formed in the substrate SUB. The TSV is an example of a first via or a second via. The interconnect W1 may be coupled to a buried power rail (BPR) buried in the substrate SUB via the TSV.

A transistor formed on the substrate SUB is not limited to a fin FET using a fin, and may be, for example, a planar MOSFET, a nanosheet FET, or a complementary FET (CFET). In the planar MOSFET and the nanosheet FET, the via TSV that supplies a power supply potential or a ground potential is coupled to the source of the transistor. In the case of the CFET, the via TSV that supplies a power supply potential or a ground potential may be coupled to the source located closest to the substrate SUB.

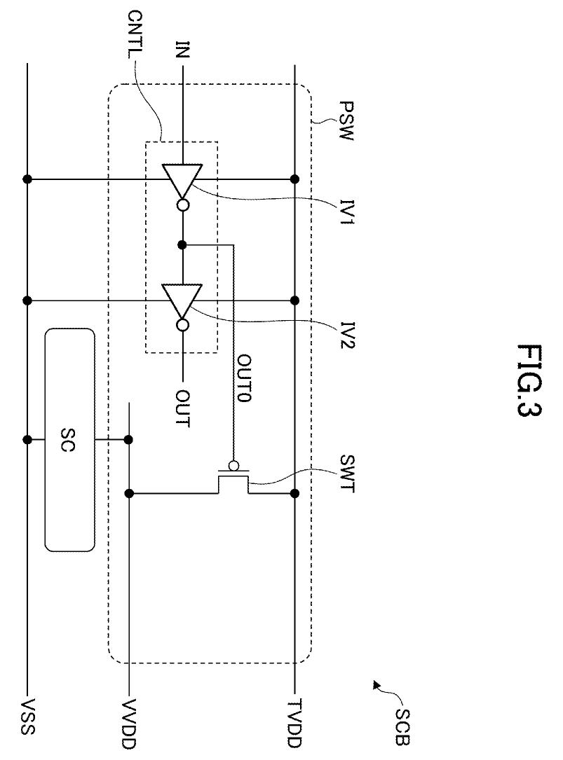

FIG. 3 illustrates an example of a circuit arranged in the standard cell block SCB of FIG. 1. The standard cell block SCB includes a power switch circuit PSW and a standard cell SC. The standard cell SC is coupled to a virtual power supply line VVDD and a ground line VSS, and operates in response to a supply of a virtual power supply potential VVDD from the virtual power supply line VVDD.

The power switch circuit PSW includes a control circuit CNTL and a switch transistor SWT. The control circuit CNTL is a buffer circuit having inverters IV1 and IV2 coupled in series between an input signal line IN and an output signal line OUT. The inverters IV1 and IV2 are coupled to a power supply line TVDD and the ground line VSS to operate. The inverter IV1 inverts the logic of an input signal IN and outputs an inverted signal as an output signal OUT0. The inverter IV2 inverts the logic of the output signal OUT0 that is output from the inverter IV1, and outputs an inverted signal as an output signal OUT.

The power supply line TVDD is an example of a first power supply line, and the power supply potential TVDD is an example of a first potential. The virtual power supply line VVDD is an example of a second power supply line, and the virtual power supply potential VVDD is an example of a second potential. The ground line VSS is an example of a third power supply line, and the ground potential VSS is an example of a third potential.

The switch transistor SWT is a PMOS transistor having a source coupled to the power supply line TVDD and a drain coupled to the virtual power supply line VVDD, and operates in response to a voltage of the output signal OUT0 that is output from the control circuit CNTL as a gate potential. While the switch transistor SWT is on, the power supply line TVDD and the virtual power supply line VVDD are electrically coupled to each other, and a power supply potential TVDD is supplied to the standard cell SC via the virtual power supply line VVDD. While the switch transistor SWT is off, an electrical coupling between the power supply line TVDD and the virtual power supply line VVDD is shut off, and the virtual power supply line VVDD is set to a floating state. Instead of the output of the inverter IV1, the input IN of the inverter IV1 or the output OUT of the inverter IV2 may be coupled to the gate of the switch transistor SWT. This is the same in other embodiments.

The control circuit CNTL may be arranged in a region different from the region where the power switch circuit PSW is arranged. The output signal OUT may be supplied to the input terminal IN of another power switch circuit PSW. The switch transistor SWT is an example of a first transistor formed above the substrate SUB and electrically coupled between the power supply line TVDD and the virtual power supply line VVDD.

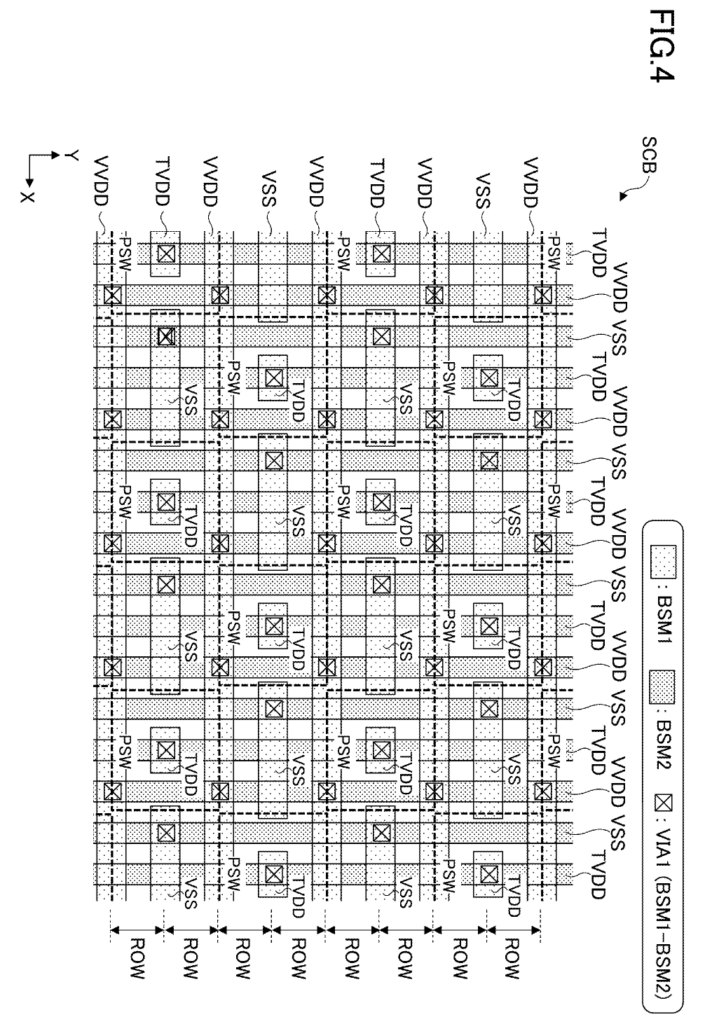

FIG. 4 is a plan view illustrating a positional relationship between the power supply lines TVDD, the virtual power supply lines VVDD, the ground lines VSS, and the vias VIA1, all of which are arranged on the back surface side BS of the semiconductor substrate SUB at respective positions overlapping the standard cell block SCB of FIG. 3, and the power switch circuits PSW in a plan view. Each interconnect of the interconnect layer BSM1 extends in an X direction, and each interconnect of the interconnect layer BSM2 extends in a Y direction, which is a second direction differing from the X direction. The X direction is an example of a first direction. The symbol “ROW” shown in FIG. 4 indicates a width of the standard cell SC in the Y direction in the interconnect layer BSM1.

The virtual power supply lines VVDD in the interconnect layer BSM1 are arranged at two intervals ROW in the Y direction. Between pairs of the virtual power supply lines VVDD adjacent to each other in the Y direction, alternately arranged along the X direction are the ground lines VSS extending in the X direction and partway interrupted at a plurality of positions and the power supply lines TVDD arranged at positions where the ground lines VSS are interrupted.

The power switch circuits PSW indicated by the thick broken line frames are arranged in, for example, a staggered manner. The standard cells SC are arranged in a region where the power switch circuits PSW are not arranged. For example, the power switch circuits PSW are arranged between pairs of the virtual power supply lines VVDD adjacent to each other in the Y direction (at two intervals ROW) so as to overlap the power supply lines TVDD extending in the X direction in a plan view.

By arranging the power supply lines TVDD in a distributed manner at the positions where the ground lines VSS are interrupted, it is possible to eliminate the need for a region having a width of the interval ROW and dedicated for the power supply lines TVDD. The power supply lines TVDD can be arranged only at positions where the power switch circuit PSW is arranged. This makes it possible to increase the arrangement density of the virtual power supply lines VVDD and the ground lines VSS in the interconnect layer BSM1 and increase the capability of supplying power to the standard cells SC, as compared to the case where a dedicated region for the power supply lines TVDD having the interval ROW is provided.

In the interconnect layer BSM2, the power supply line TVDD, the virtual power supply line VVDD, and the ground line VSS are arranged in a repeated pattern in this order in the X direction. The virtual power supply lines VVDD of the interconnect layers BSM1 and BSM2 are coupled to each other through the vias VIA1 arranged at the intersections. The power supply lines TVDD of the interconnect layers BSM1 and BSM2 are coupled to each other through the vias VIA1 arranged at the intersections. The ground lines VSS of the interconnect layers BSM1 and BSM2 are coupled to each other through the vias VIA1 arranged at the intersections.

The virtual power supply lines VVDD may be omitted in the interconnect layer BSM2. In this case, in the interconnect layer BSM2, the power supply lines TVDD and the ground lines VSS are alternately arranged along the X direction. Although not particularly limited, the arrangement density of the power switch circuits PSW may be set lower than that in FIG. 4. In this case, the interval of interruptions in the ground line VSS extending in the X direction is set to be wider than that in FIG. 4.

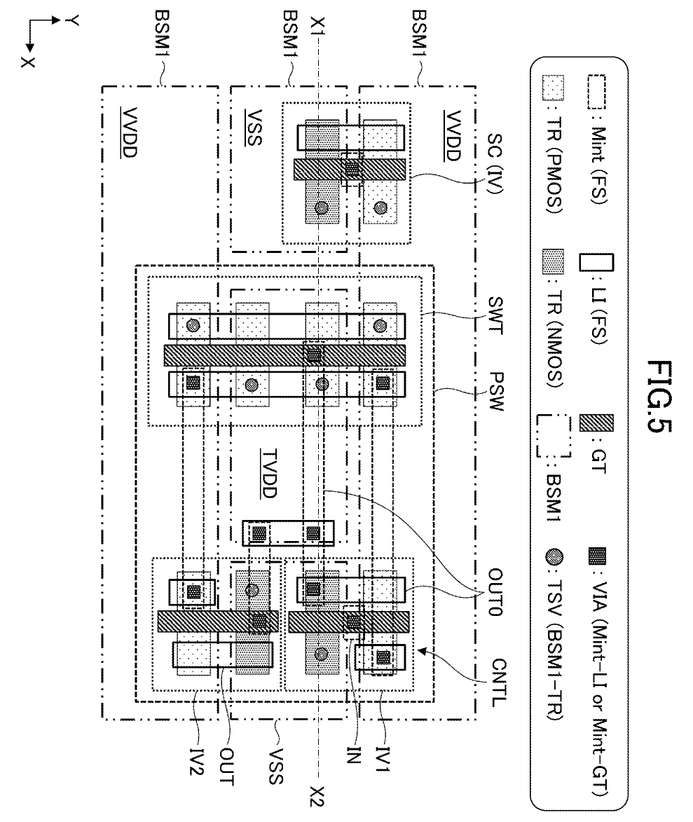

FIG. 5 illustrates an example of a layout in the power switch circuit PSW illustrated in FIGS. 3 and 4. In the legend illustrated in FIG. 5 and the drawings thereafter, the symbol “Mint” denotes an interconnect formed in the metal interconnect layer Mint closest to the substrate SUB among the plurality of metal interconnect layers. The symbol “LI” denotes a local interconnect formed in an interconnect layer closer to the substrate SUB than the Mint layer. The interconnect LI can be directly coupled to a source and a drain of the transistor. The symbol “GT” denotes a gate of the transistor. The symbol “VIA” denotes a via that couples the Mint interconnect and the local interconnect LI or a via that couples the Mint interconnect and the gate interconnect GT.

The symbol “TR (PMOS)” denotes a transistor region (source, drain, and channel) of a PMOS transistor. The symbol “TR (NMOS)” denotes a transistor region (source, drain, and channel) of an NMOS transistor. For example, in the fin FET, a fin is formed in the region TR. In the nanosheet FET, a semiconductor layer is formed as a source and a drain in the region TR, and a nanosheet as a channel is formed between the source and the drain.

The power switch circuit PSW includes a switch transistor SWT and a control circuit CNTL (buffer circuit) arranged in the X direction in a plan view. For example, the power switch circuit PSW is designed as one cell. The switch transistor SWT is arranged at a position overlapping the virtual power supply lines VVDD and the power supply line TVDD of the interconnect layer BSM1 in a plan view.

In the switch transistor SWT, the sources of the PMOS transistors overlapping the power supply line TVDD of the interconnect layer BSM1 in a plan view is directly coupled to the TSVs coupled to the power supply line TVDD of the interconnect layer BSM1. The TSVs directly coupled to the sources of the PMOS transistors overlapping the power supply line TVDD of the interconnect layer BSM1 in a plan view are an example of a first via. In the switch transistor SWT, the sources of the PMOS transistors that do not overlap the power supply line TVDD of the interconnect layer BSM1 in a plan view are coupled to, via the local interconnect LI, the sources of the PMOS transistors coupled to the TSVs of the power supply line TVDD. The expression “directly coupled” means that a conductor included in the TSV is in contact with a source, a drain, or the like of each transistor, and also includes, for example, a case where the TSV includes a plurality of layers of conductors, a part of the plurality of layers of conductors being in contact with the source or the drain of the transistor.

In the switch transistor SWT, the drains of the PMOS transistors that overlap the virtual power supply line VVDD of the interconnect layer BSM1 in a plan view are directly coupled to the virtual power supply lines VVDD of the interconnect layer BSM1 via the TSVs, respectively. In the switch transistor SWT, the drains of the PMOS transistors that do not overlap the virtual power supply lines VVDD of the interconnect layer BSM1 in a plan view are coupled to the drains of the PMOS transistors coupled to the TSVs of the virtual power supply lines VVDD via the local interconnects LI.

The control circuit CNTL is arranged at a position overlapping the virtual power supply lines VVDD and the ground line VSS of the interconnect layer BSM1 in a plan view. The sources of the NMOS transistors of the control circuit CNTL are directly coupled to the ground line VSS of the interconnect layer BSM1 via the TSVs. The control circuit CNTL is not arranged at a position overlapping the power supply line TVDD of the interconnect layer BSM1 in a plan view. For this reason, the TSVs (TVDD) cannot be directly coupled to the sources of the PMOS transistors of the control circuit CNTL (inverters IV1 and IV2).

Therefore, the sources of the PMOS transistors of the control circuit CNTL are electrically coupled to the sources of the PMOS transistors of the switch transistor SWT via the local interconnects LI and the Mint interconnect. This allows the sources of the PMOS transistors of the control circuit CNTL to be electrically coupled to the power supply line TVDD of the interconnect layer BSM1. The PMOS transistors of the inverters IV1 and IV2 are an example of a second transistor formed above the substrate SUB. The sources of the PMOS transistors of the control circuit CNTL may be electrically coupled to the sources of the PMOS transistors of the switch transistor SWT via an interconnect in a layer above the Mint interconnect.

In other words, the sources of the PMOS transistors of the control circuit CNTL can be electrically coupled to the power supply line TVDD of the interconnect layer BSM1 without depending on the layout in the power supply line TVDD formed in the interconnect layer BSM1 on the back surface side BS of the substrate SUB. As a result, the degree of freedom of the layout in the power switch circuit PSW can be increased as compared with the case where the local interconnect LI and the Mint interconnect are not used for the coupling between the source of the PMOS transistor and the power supply line TVDD.

The source of the PMOS transistor of the inverter IV arranged in the standard cell SC is directly coupled to the virtual power supply line VVDD of the interconnect layer BSM1 via the TSV. The source of the NMOS transistor of the inverter IV arranged in the standard cell SC is directly coupled to the ground line VSS of the interconnect layer BSM1 via the TSV.

The control circuit CNTL (inverters IV1 and IV2) may be included in the power supply switch circuit PSW or arranged separately from the power supply switch circuit PSW. In this case, the power switch circuit PSW and the control circuit CNTL may be designed as different cells. Alternatively, a plurality of power switch circuits PSW may be controlled by one control circuit CNTL.

The power supply line TVDD and the ground line VSS in the interconnect layer BSM1 are coupled to the corresponding power supply line TVDD and ground line VSS in the interconnect layer BSM2 (not illustrated), respectively. In the case where the virtual power supply lines VVDD are arranged in the interconnect layer BSM2, the power supply line TVDD may be coupled to the virtual power supply lines VVDD in the interconnect layer BSM1.

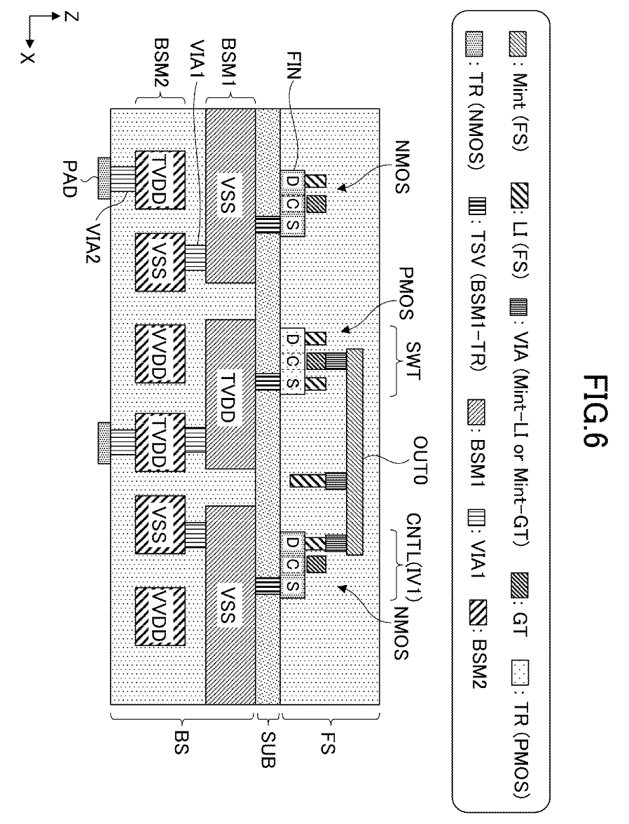

FIG. 6 illustrates an example of a cross section taken along line X1-X2 in FIG. 5. The ground line VSS formed in the interconnect layer BSM1 on the back surface side BS is coupled to the sources S (N-type impurity region) of the NMOS transistors formed on the front surface FS side via the TSV formed in the substrate SUB. Similarly, the power supply line TVDD formed in the interconnect layer BSM1 on the back surface side BS is coupled to the source S (P-type impurity region) of the PMOS transistor formed on the front surface side FS via the TSV formed in the substrate SUB.

In each fin FIN, a channel C is arranged between a source S and a drain D. A gate GT is arranged on the channel C, with a gate insulating film (not illustrated) being interposed between the gate GT and the channel C. An output signal OUT0 that is output from the inverter IV1 of the control circuit CNTL is supplied to the gate GT of the PMOS transistor of the power supply switch circuit PSW via the local interconnect LI, the Mint interconnect, and the local interconnect LI. In FIG. 6, two interconnect layers BSM1 and BSM2 are arranged on the back surface side BS, but three or more interconnect layers BSM may be arranged.

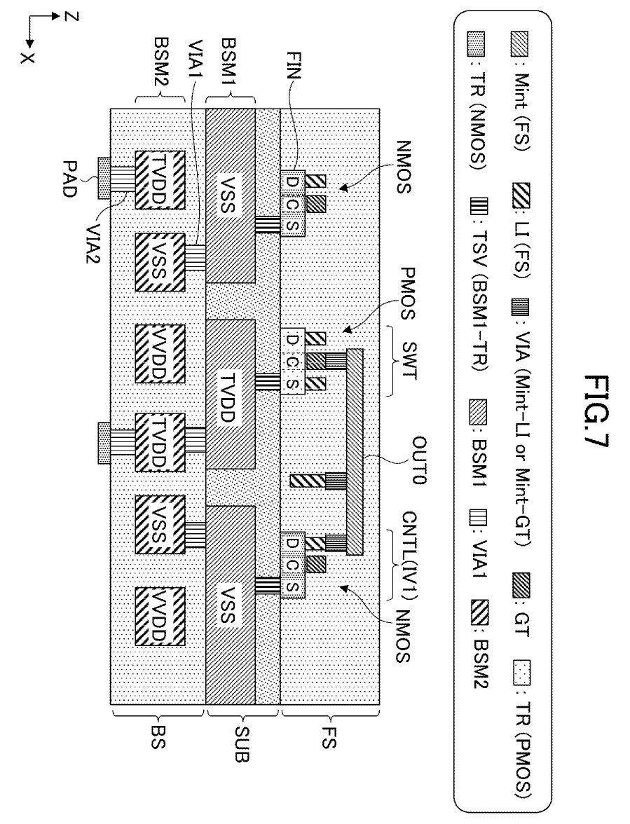

FIG. 7 illustrates another example of a cross section taken along line X1-X2 in FIG. 5. FIG. 7 is the same as the cross-sectional structure of FIG. 6 except that the interconnect layer BSM1 is formed below but within the substrate SUB and on the back surface side BS of the substrate SUB. Note that the interconnect layer BSM1 illustrated in FIG. 7 is different from the buried power rail BPR (FIG. 2) buried in the front surface side FS of the substrate SUB. The interconnect layer BSM1 may be formed inside the lower portion of the substrate SUB without being exposed on the back surface side BS of the substrate SUB.

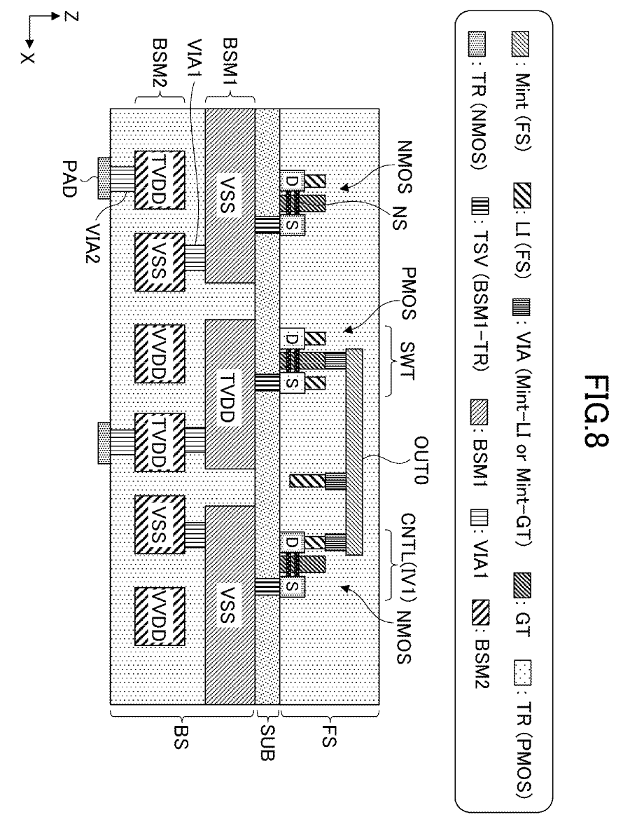

FIG. 8 illustrates yet another example of a cross section taken along line X1-X2 in FIG. 5. FIG. 8 is the same as the cross-sectional structure of FIG. 5 except that the transistor formed on the substrate SUB is a nanosheet FET. The nanosheet FET includes a semiconductor layer having a source S and a drain D, a nanosheet NS having a semiconductor material formed between the source S and the drain D, and a gate electrode GT formed with a gate insulating film (not illustrated) interposed between the gate electrode GT and the nanosheet NS. The nanosheet FET may be arranged instead of the fin FET illustrated in FIG. 7.

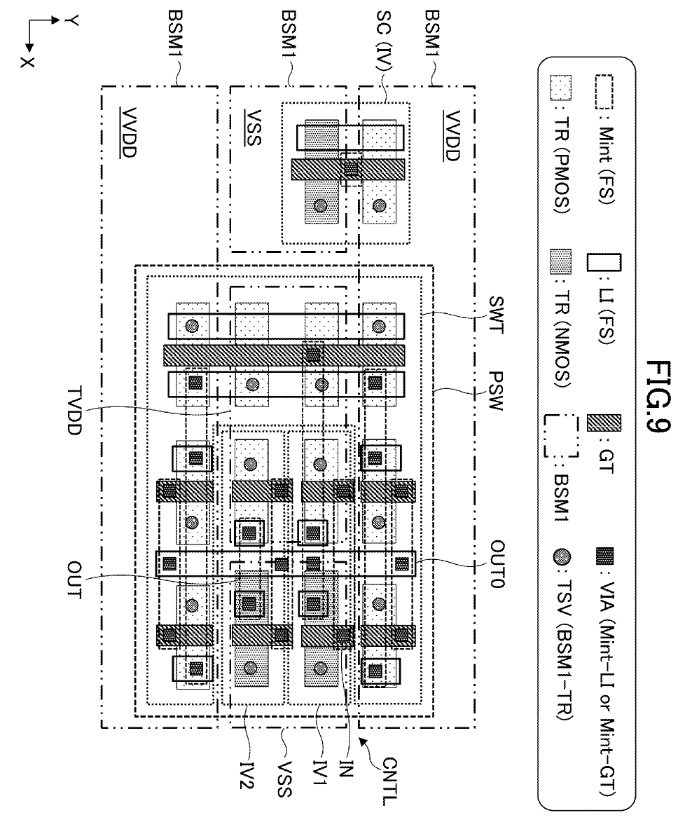

FIG. 9 illustrates a first modified example of a layout in the power switch circuit PSW illustrated in FIG. 3. The layout illustrated in FIG. 9 is similar to the layout illustrated in FIG. 5, except that the layout in the control circuit CNTL differs from that of FIG. 5 and the size of the PMOS transistor of the switch transistor SWT is larger than that in FIG. 5. The switch transistor SWT and the control circuit CNTL are arranged side by side in the X direction in a plan view.

The two inverters IV1 and IV2 of the control circuit CNTL are arranged along the Y direction at positions overlapping the power supply lines TVDD and the ground line VSS of the interconnect layer BSM1 in a plan view. Since the PMOS transistors of the inverters IV1 and IV2 are arranged at positions overlapping the power supply line TVDD of the interconnect layer BSM1 in a plan view, the sources of these PMOS transistors can be directly coupled to the power supply line TVDD of the interconnect layer BSM1 via the TSVs.

The PMOS transistors of the switch transistor SWT are also arranged at positions overlapping the virtual power supply lines VVDD of the interconnect layer BSM1 in a plan view on both sides of the control circuit CNTL in the Y direction (hereinafter, these PMOS transistors will be referred to as “additional PMOS transistors”). The sources of the additional PMOS transistors cannot be directly coupled to the power supply line TVDD of the interconnect layer BSM1 via the TSVs.

Therefore, the sources of the additional PMOS transistors are electrically coupled to the sources of the PMOS transistors of the switch transistor SWT arranged at positions overlapping the power supply lines TVDD of the interconnect layer BSM1 in a plan view via the local interconnect LI and the Mint interconnect. This allows the sources of the additional PMOS transistors to be electrically coupled to the power supply line TVDD of the interconnect layer BSM1.

In other words, the sources of the PMOS transistors of the switch transistor SWT can be electrically coupled to the power supply line TVDD of the interconnect layer BSM1 without depending on the layout in the power supply line TVDD formed in the interconnect layer BSM1 on the back surface side BS of the substrate SUB. As a result, the degree of freedom of the layout in the power switch circuit PSW can be increased.

The control circuit CNTL (inverters IV1 and IV2) may be arranged separately from the power supply switch circuit PSW. In this case, the power switch circuit PSW and the control circuit CNTL may be designed as different cells. Alternatively, a plurality of power switch circuits PSW may be controlled by one control circuit CNTL.

The virtual power supply lines VVDD, the power supply line TVDD, and the ground line VSS in the interconnect layer BSM1 are coupled to the corresponding virtual power supply lines VVDD, power supply line TVDD, and ground line VSS in the interconnect layer BSM2 (not illustrated), respectively. The virtual power supply lines VVDD do not need to be arranged in the interconnect layer BSM2.

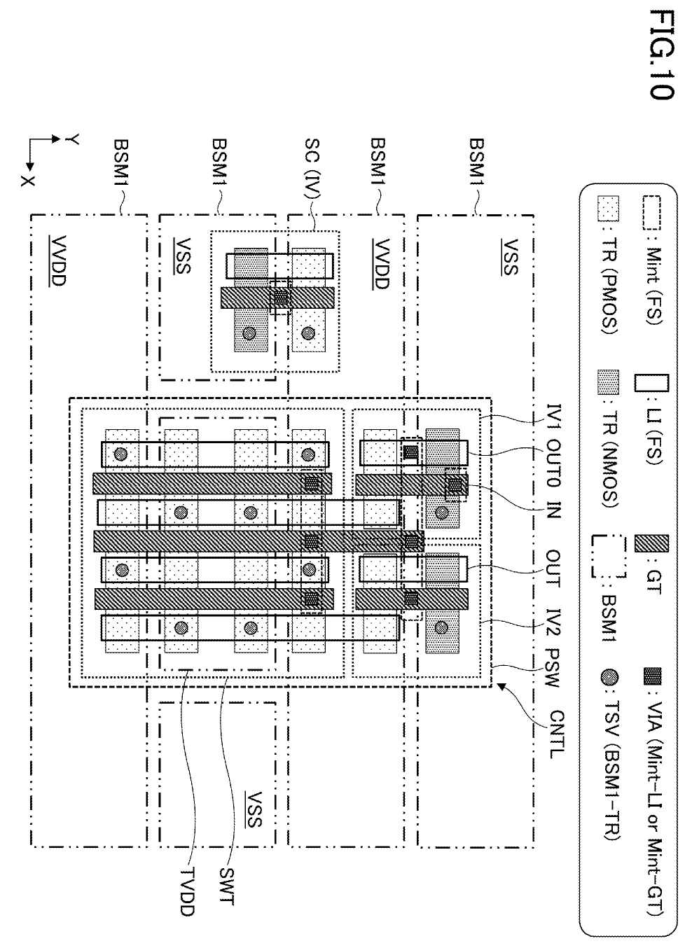

FIG. 10 illustrates a second modified example of a layout in the power switch circuit PSW illustrated in FIG. 3. In FIG. 10, the switch transistor SWT and the control circuit CNTL are arranged side by side in the Y direction in a plan view. The switch transistor SWT is, similarly to the layout illustrated in FIG. 5, arranged at a position overlapping the virtual power supply lines VVDD and the power supply line TVDD of the interconnect layer BSM1 in a plan view. The control circuit CNTL is arranged at a position overlapping the virtual power supply lines VVDD and the ground lines VSS of the interconnect layer BSM1 in a plan view.

The control circuit CNTL (inverters IV1 and IV2) is not arranged at a position overlapping the power supply line TVDD of the interconnect layer BSM1 in a plan view. Therefore, the sources of the PMOS transistors of the control circuit CNTL is electrically coupled to the sources of the PMOS transistors of the switch transistor SWT via the local interconnect LI. This allows the sources of the PMOS transistors of the control circuit CNTL to be electrically coupled to the power supply line TVDD of the interconnect layer BSM1.

The control circuit CNTL (inverters IV1 and IV2) may be arranged separately from the power supply switch circuit PSW. In this case, the power switch circuit PSW and the control circuit CNTL may be designed as different cells. Alternatively, a plurality of power switch circuits PSW may be controlled by one control circuit CNTL.

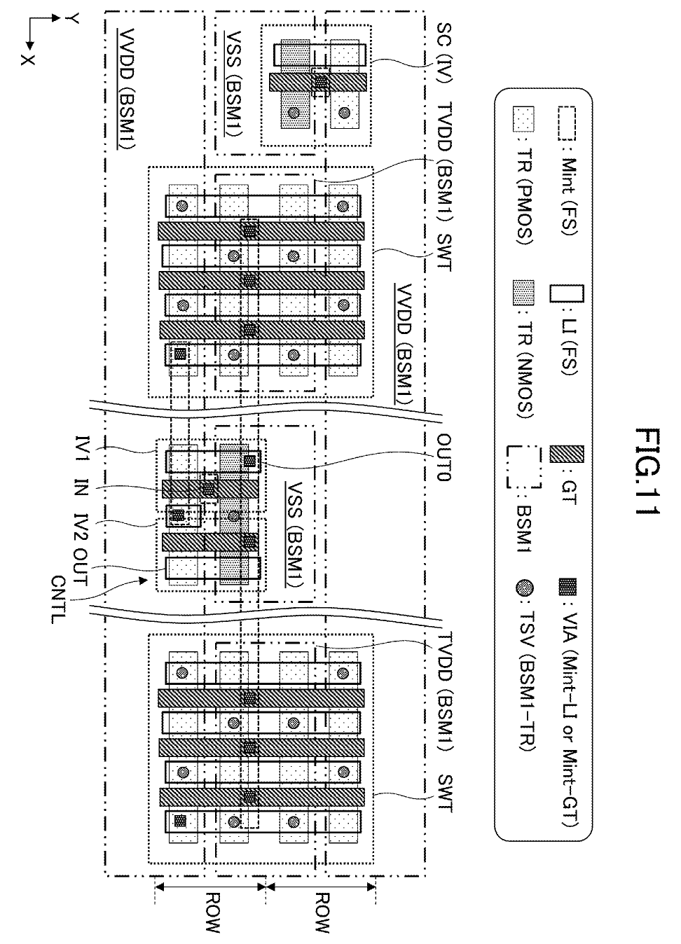

FIG. 11 illustrates a third modified example of a layout in the power switch circuit PSW illustrated in FIG. 3. In FIG. 11, the control circuit CNTL is arranged between the two switch transistors SWT in the X direction. An output signal OUT0 that is output from the first-stage inverter IV1 of the control circuit CNTL is supplied in common to the gates of the PMOS transistors of the two switch transistors SWT via the Mint interconnect.

The two switch transistors SWT and the control circuit CNTL are arranged using two intervals ROW. One or two of the two switch transistors SWT and the control circuit CNTL may be arranged at different positions in the Y direction. For example, each switch transistor SWT and the control circuit CNTL are designed as cells different from each other.

The layout of the elements of each switch transistor SWT is similar to the layout of the elements of the switch transistor SWT in FIG. 10. The layout of the elements of the control circuit CNTL is similar to the layout of the elements of the control circuit CNTL of FIG. 10 except that the sources of the NMOS transistors of the inverters IV1 and IV2 are common to each other.

Even in FIG. 11, the control circuit CNTL is not arranged at a position overlapping the power supply line TVDD of the interconnect layer BSM1 in a plan view. Therefore, the source of the PMOS transistor of the control circuit CNTL is electrically coupled to the source of the PMOS transistor of the switch transistor SWT via the local interconnect LI and the Mint interconnect. This allows the source of the PMOS transistor of the control circuit CNTL to be electrically coupled to the power supply line TVDD of the interconnect layer BSM1.

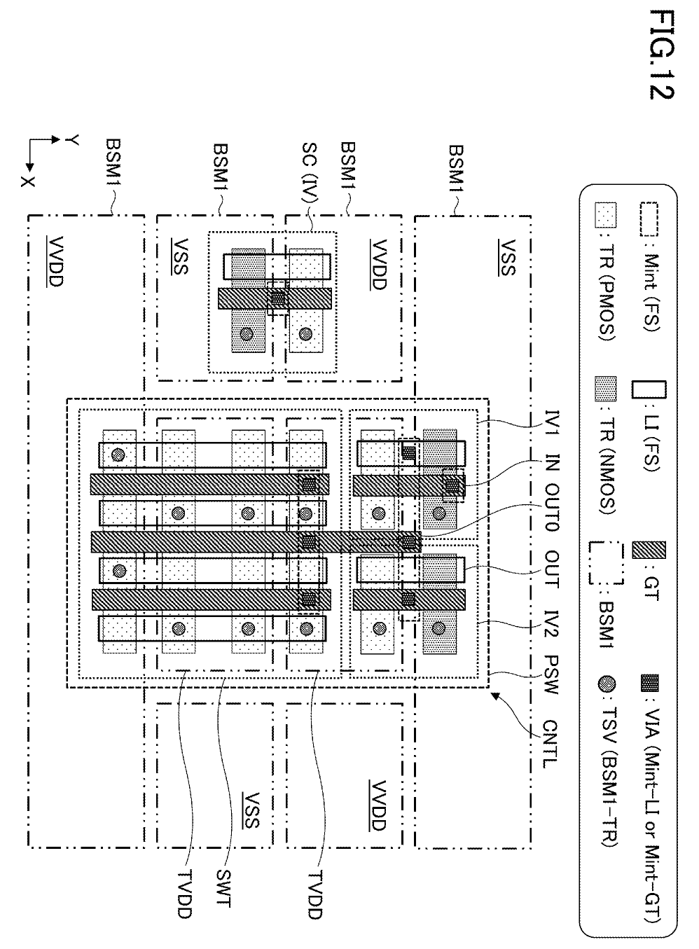

FIG. 12 illustrates a fourth modified example of a layout in the power switch circuit PSW illustrated in FIG. 3. In FIG. 12, the switch transistor SWT and the control circuit CNTL are arranged side by side in the Y direction in a plan view. The layout of the elements of the switch transistor SWT is similar to the layout of the elements of the switch transistor SWT in FIG. 10. The layout of the elements of the control circuit CNTL is similar to the layout of the elements of the control circuit CNTL in FIG. 10.

In FIG. 12, the ground lines VSS and the virtual power supply lines VVDD in the interconnect layer BSM1 are interrupted to provide a free space, and two power supply lines TVDD are arranged in the free space along the Y direction. In other words, the ground lines VSS and the power supply lines TVDD are alternately arranged along the X direction, and the virtual power supply lines VVDD and the power supply lines TVDD are alternately arranged along the X direction.

This allows the sources of the PMOS transistors of the control circuit CNTL (inverters IV1 and IV2) to be directly coupled to the power supply lines TVDD of the interconnect layer BSM1 via the TSVs. The two power supply lines TVDD in the interconnect layer BSM1 may be collectively arranged as one power supply line TVDD.

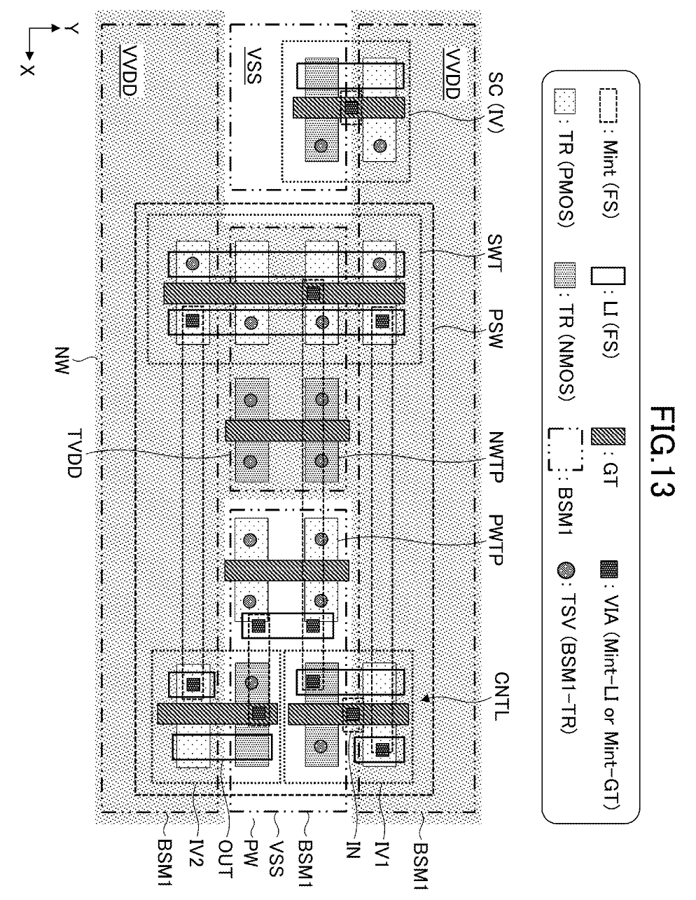

FIG. 13 illustrates a fifth modified example of a layout in the power switch circuit PSW illustrated in FIG. 3. The power supply switch circuit PSW illustrated in FIG. 13 is similar to the power supply switch circuit PSW in FIG. 5 except that an N-type well tap NWTP and a P-type well tap PWTP are arranged between the switch transistor SWT and the control circuit CNTL arranged in the X direction.

The well taps NWTP and PWTP are arranged side by side in the X direction. The power supply switch circuit PSW has the configuration similar to that of the power supply switch circuit PSW of FIG. 5 except that the power supply switch circuit PSW has the well taps NWTP and PWTP. The well tap NWTP is an example of a first well tap, and the well tap PWTP is an example of a second well tap. In FIG. 13, the well tap NWTP and the PWTP are arranged between the switch transistor SWT and the control circuit CNTL in the X direction, but the arrangement is not limited thereto. For example, the well tap PWTP may be arranged at a position overlapping the P-type well region on the opposite side of the P-type well region PW at the position overlapping the control circuit CNTL in the X direction.

The well tap NWTP is arranged at a position overlapping the power supply line TVDD of the interconnect layer BSM1 in a plan view. The well tap NWTP is formed by an NMOS transistor whose source and drain are directly coupled to the power supply line TVDD of the interconnect layer BSM1 via the TSV. This makes it possible to supply the power supply potential TVDD to an N-type well region NW, which is the substrate region (shaded region) of the PMOS transistor. The TSVs directly coupled to the source and drain of the well tap NWTP are an example of a second via.

The well tap PWTP is arranged at a position overlapping the ground line VSS of the interconnect layer BSM1 in a plan view. The well tap PWTP is formed by a PMOS transistor whose source and drain are directly coupled to the ground line VSS of the interconnect layer BSM1 via the TSV. This makes it possible to supply the ground potential VSS to a P-type well region PW, which is the substrate region (shaded region) of the NMOS transistor. The NMOS transistor is an example of a third transistor having a conductivity type opposite to that of the PMOS transistor. The TSVs directly coupled to the source and drain of the well tap PWTP are an example of a third via.

The well region NW is an N-type impurity region formed in the substrate SUB and is electrically coupled to the channel of the fin FET (PMOS). The well region PW is a P-type substrate SUB or a P-type impurity region formed in the substrate SUB and is electrically coupled to the channel of the fin FET (NMOS).

As described above, in the first embodiment, even when the sources of the PMOS transistors are not arranged at positions overlapping the power supply lines TVDD of the interconnect layer BSM1 in a plan view, the sources of the PMOS transistors can be electrically coupled to the power supply line TVDD of the interconnect layer BSM1. As a result, the degree of freedom of the layout in the power switch circuit PSW can be increased as compared with the case where the local interconnect LI and the Mint interconnect are not used for the coupling between the sources of the PMOS transistors and the power supply lines TVDD.

By arranging the power supply lines TVDD in a distributed manner at the positions where the ground lines VSS are interrupted, it is possible to eliminate the need for a region having a width of the interval ROW and dedicated for the power supply lines TVDD. The power supply lines TVDD can be arranged only at positions where the power switch circuit PSW is arranged. This makes it possible to increase the arrangement density of the virtual power supply lines VVDD and the ground lines VSS in the interconnect layer BSM1 and increase the capability of supplying power to the standard cells SC, as compared to the case where a dedicated region for the power supply lines TVDD having the interval ROW is provided.

The source and drain of the NMOS transistor forming the well tap NWTP are directly coupled to the power supply line TVDD of the interconnect layer BSM1 via the TSV, thereby enabling the power supply potential TVDD to be supplied to the well region NW from the back surface side BS of the substrate SUB. The source and drain of the PMOS transistor forming the well tap PWTP are directly coupled to the ground line VSS of the interconnect layer BSM1 via the TSV, thereby the ground potential VSS can be supplied to the well region PW from the back surface side BS of the substrate SUB.

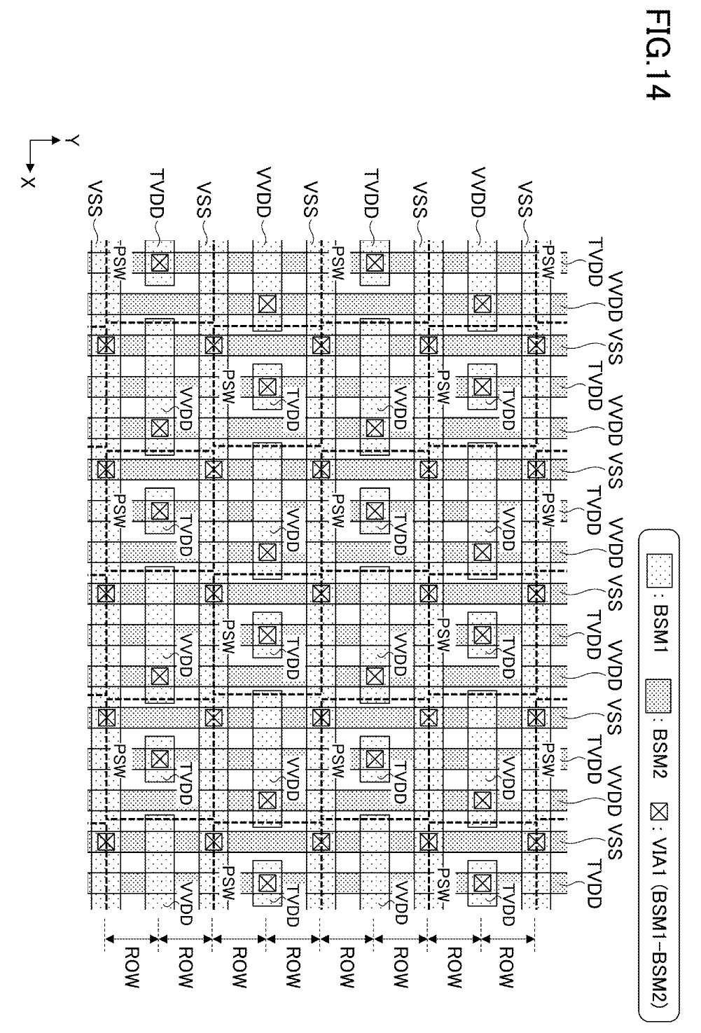

FIG. 14 illustrates an example of a layout of the power supply lines arranged on the back surface side of the semiconductor substrate in the semiconductor device of the second embodiment. The same symbols are given to the same elements as those in FIG. 4, and the detailed description thereof will be omitted.

In FIG. 14, the ground lines VSS of the interconnect layer BSM1 are formed to extend in the X direction without being interrupted. Between pairs of the ground lines VSS adjacent to each other in the Y direction, the virtual power supply lines VVDD extending in the X direction and partway interrupted at a plurality of positions and the power supply lines TVDD arranged at positions where the virtual power supply lines VVDD are interrupted are alternately arranged along the X direction. The power switch circuits PSW indicated by the thick broken line frames are arranged in a staggered manner. The other configurations illustrated in FIG. 14 are the same as those in FIG. 4.

By arranging the power supply lines TVDD in a distributed manner at the positions where the virtual power supply lines VVDD are interrupted, it is possible to eliminate the need for a region having a width of the interval ROW and dedicated for the power supply lines TVDD, similarly to the layout of FIG. 4. The power supply lines TVDD can be arranged only at positions where the power switch circuit PSW is arranged. This makes it possible to increase the arrangement density of the virtual power supply lines VVDD and the ground lines VSS in the interconnect layer BSM1 and increase the capability of supplying power to the standard cells SC, as compared to the case where a dedicated region for the power supply lines TVDD having the interval ROW is provided.

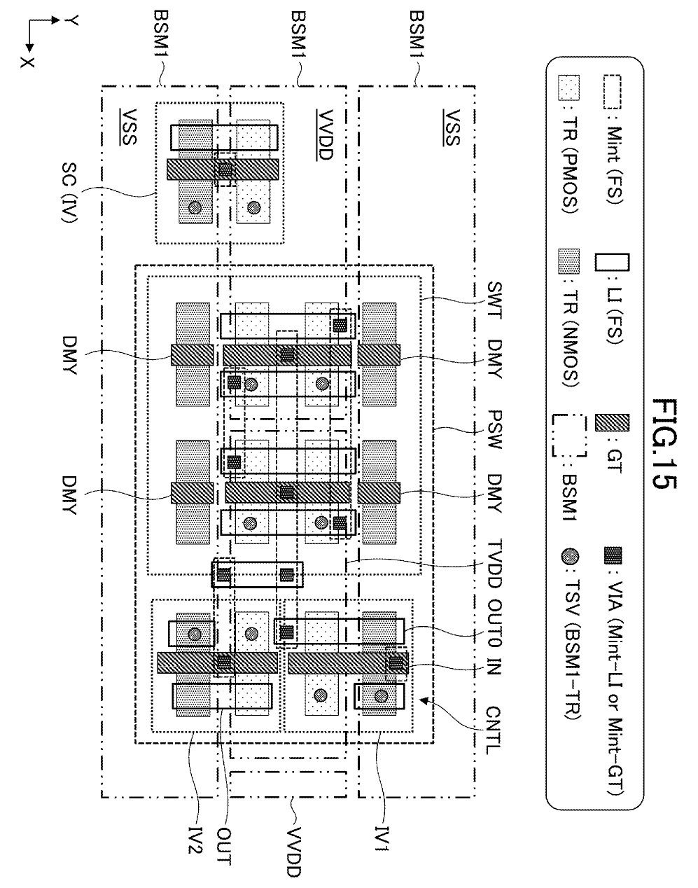

FIG. 15 illustrates an example of a layout of the power switch circuit PSW illustrated in FIG. 14. The same symbols are given to the same elements as those in FIG. 5, and the detailed description thereof will be omitted. In the power switch circuit PSW, the switch transistor SWT and the control circuit CNTL are arranged side by side in the X direction in a plan view.

The PMOS transistors of the switch transistor SWT are arranged at positions overlapping the virtual power supply line VVDD and the power supply line TVDD of the interconnect layer BSM1 in a plan view. The control circuit CNTL is arranged at a position overlapping the power supply line TVDD and the ground line VSS of the interconnect layer BSM1 in a plan view. The layout in the inverter IV arranged in the standard cell SC is similar to the layout in the inverter IV arranged in the standard cell SC of FIG. 5.

In the switch transistor SWT, the sources of the PMOS transistors arranged at positions overlapping the power supply line TVDD of the interconnect layer BSM1 in a plan view are directly coupled to the TSVs coupled to the power supply line TVDD of the interconnect layer BSM1. In the switch transistor SWT, the sources of the PMOS transistors arranged at positions overlapping the virtual power supply line VVDD of the interconnect layer BSM1 in a plan view are electrically coupled to the sources of the PMOS transistors coupled to the TSV via the local interconnects LI and the Mint interconnects. In the switch transistor SWT, a dummy transistor DMY (NMOS) are arranged in regions overlapping the ground line VSS of the interconnect layer BSM1 in a plan view.

In the control circuit CNTL, the sources of the PMOS transistors of the inverters IV1 and IV2 are directly coupled to the power supply line TVDD of the interconnect layer BSM1 via the TSVs. In the control circuit CNTL, the sources of the NMOS transistors of the inverters IV1 and IV2 are directly coupled to the ground line VSS of the interconnect layer BSM1 via the TSVs.

In FIG. 15, the switch transistor SWT and the control circuit CNTL are arranged side by side in the X direction in a plan view, but the switch transistor SWT and the control circuit CNTL may be arranged side by side in the Y direction in a plan view as illustrated in FIG. 10 or 12.

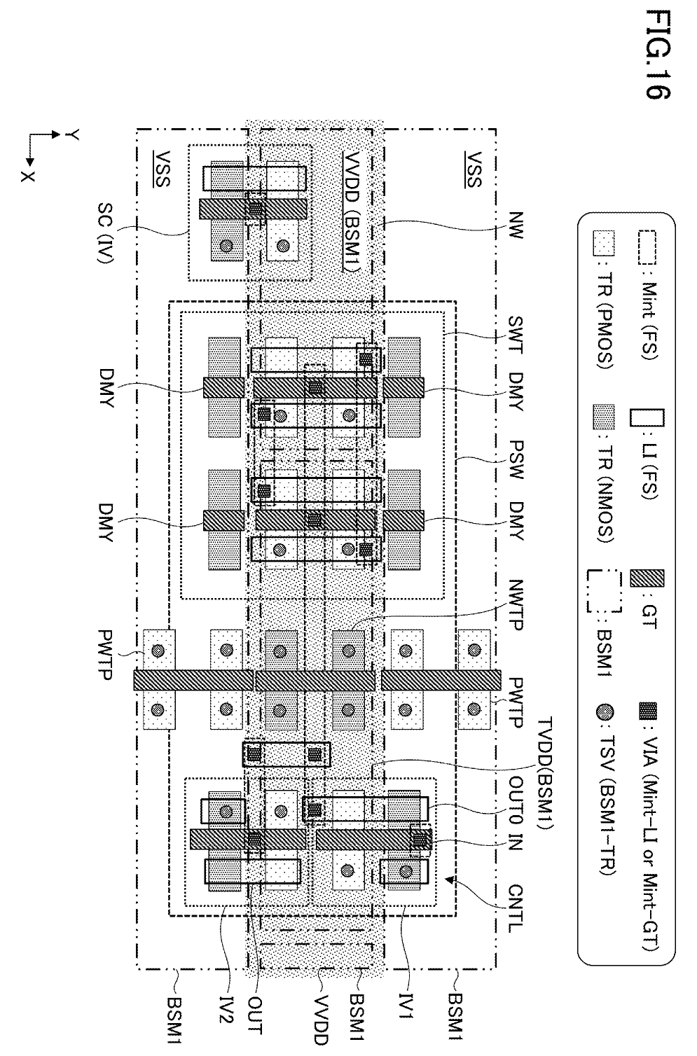

FIG. 16 illustrates a modified example of a layout in the power switch circuit PSW illustrated in FIG. 14. The same symbols are given to the same elements as those in FIG. 13, and the detailed description thereof will be omitted. The power supply switch circuit PSW illustrated in FIG. 16 is similar to the power supply switch circuit PSW in FIG. 15 except that the N-type well tap NWTP and the P-type well tap PWTP are arranged between the switch transistor SWT and the control circuit CNTL arranged in the X direction. The well taps NWTP and PWTP are arranged side by side in the Y direction.

The well tap NWTP is arranged at a position overlapping the power supply line TVDD of the interconnect layer BSM1 in a plan view. The well tap NWTP is formed by an NMOS transistor whose source and drain are directly coupled to the power supply line TVDD of the interconnect layer BSM1 via the TSV. This makes it possible to supply the power supply potential TVDD to an N-type well region NW, which is the substrate region (shaded region) of the PMOS transistor.

The well tap PWTP is arranged at a position overlapping the ground line VSS of the interconnect layer BSM1 in a plan view. The well tap PWTP is formed by a PMOS transistor whose source and drain are directly coupled to the ground line VSS of the interconnect layer BSM1 via the TSV. This makes it possible to supply the ground potential VSS to a P-type well region PW, which is the substrate region (shaded region) of the NMOS transistor.

As described above, the second embodiment can also obtain effects similar to those of the first embodiment. For example, even in the case where the power supply lines TVDD of the interconnect layer BSM1 are arranged in a distributed manner, the sources of the PMOS transistors can be electrically coupled to the power supply lines TVDD of the interconnect layer BSM1, and the flexibility of the layout in the power switching circuit PSW can be increased. By arranging the power supply lines TVDD in a distributed manner at the positions where the ground lines VSS are interrupted, the arrangement density of the virtual power supply lines VVDD and the ground lines VSS in the interconnect layer BSM1 can be increased, and the capability of supplying power to the standard cells SC can be increased.

Although the present invention has been described above based on the respective embodiments, the present invention is not limited to the requirements illustrated in the above embodiments. These embodiments can be changed within a range not departing from the gist of the present invention, and can be appropriately determined according to the application form.

What is claimed is:

1. A semiconductor device, comprising:
a substrate in which a first via is formed;
a first power supply line supplied with a first potential, a second power supply line supplied with a second potential, and a third power supply line supplied with a third potential, the first power supply line, the second power supply line, and the third power supply line being formed below the substrate; and
a power switch circuit including a first transistor formed above the substrate and electrically coupled between the first power supply line and the second power supply line and a second transistor formed above the substrate, wherein
the first power supply line, the second power supply line, and the third power supply line each extend in a first direction in a plan view,
the first transistor includes a first source and a first drain,
the first transistor is arranged at a position overlapping the first power supply line in a plan view,
the first source is coupled to the first via coupled to the first power supply line,
the second transistor includes a second source and a second drain,
the second transistor is arranged at a position overlapping the second power supply line in a plan view, and
the second source is electrically coupled to the first source via an interconnect formed above the substrate.

2. The semiconductor device according to claim 1, wherein
the third power supply line extending in the first direction is partway interrupted at a plurality of positions,
the first power supply line is arranged in a region where the third power supply line is interrupted, and
the second power supply line is arranged adjacent to the third power supply line and the first power supply line, the third power supply line and the first power supply line being arranged side by side along the first direction.

3. The semiconductor device according to claim 1, wherein
the second power supply line extending in the first direction is partway interrupted at a plurality of positions,
the first power supply line is arranged in a region where the second power supply line is interrupted, and
the third power supply line is arranged adjacent to the second power supply line and the first power supply line, the second power supply line and the first power supply line being arranged side by side along the first direction.

4. The semiconductor device according to claim 1, further comprising a control circuit coupled to a gate of the first transistor, wherein
the second transistor is included in the control circuit.

5. The semiconductor device according to claim 1, wherein
the second transistor is electrically coupled between the first power supply line and the second power supply line.

6. The semiconductor device according to claim 1, wherein
the first transistor and the second transistor are arranged side by side in the first direction.

7. The semiconductor device according to claim 1, wherein
the first transistor and the second transistor are arranged side by side in a second direction different from the first direction in a plan view.

8. The semiconductor device according to claim 1, further comprising:
a first well tap arranged above the substrate and at a position overlapping the first power supply line in a plan view, coupled to a second via formed in the substrate, and configured to supply the first potential to first well of both the first transistor and the second transistor, wherein
the second via is coupled to the first power supply line.

9. The semiconductor device according to claim 1, further comprising a second well tap arranged above the substrate and at a position overlapping the third power supply line in a plan view, coupled to a third via formed in the substrate, and configured to supply the third potential to a second well of a third transistor, a conductive type of the third transistor being opposite to a conductive type of the first transistor, wherein
the third via is coupled to the third power supply line.
